(19) United States
(12) Patent Application Publication
(10) Pub. No.: US 2009/0027852 A1
(43) Pub. Date: Jan. 29, 2009

(54) AIRFLOW REDIRCTION DEVICE

(76) Inventors: Arlen L. Roesner, Ft. Collins, CO (US); Joseph White, Windsor, CO (US); Erick Tuttle, 7840 South 2000 East, South Weber, UT (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/828,888

(22) Filed: Jul. 26, 2007

(51) Int. Cl. H05K 7/20; H05K 5/00

(52) U.S. Cl. 361/690; 454/184

(57) ABSTRACT

An air flow redirection device is disclosed. The air flow redirection device comprises a frame with a main hinge coupled to a top back edge of the frame. A plate is coupled to the main hinge and configured to rotate about the main hinge from an open position to a closed position. In the closed position the plate rests on top of the frame with a bottom side of the plate facing the bottom of the frame. A plurality of blocking fingers are coupled to the bottom side of the plate using a secondary hinge in a line parallel with, and adjacent to, the primary hinge. Each blocking finger is spring loaded away from the plate.

### BACKGROUND

In a computer system that utilizes upstream fans for cooling, a pressurized volume of air is directed towards the downstream components. Imbalances in airflow impedance in the downstream area can cause the airflow to bypass critical components. Some printed circuit (PC) assemblies have optional components. When the optional components are missing from the PC assemblies, gaps or open/empty regions are created in the airflow path. The gaps or open/empty regions create imbalances in airflow impedance across the PC assembly. The air tends to flow into the gaps or open/empty region and can cause the airflow to bypass critical components.

One type of PC assembly that has optional components is the memory boards in computer systems. A primary memory boards may have a number of slots available for the installation of optional printed circuit assembly such as a dual in-line memory module (DIMM). Typically the DIMMs are vertically installed into the open slots in the primary memory board. In some configurations all the slots in the primary memory board may not be filled. These empty slots create gaps or open/empty regions in the assembly. Air flowing through the assembly tends to flow into and through these gaps, thereby reducing the amount of air flowing past the slots with DIMMs installed.

Currently there are two general solutions to this problem. One solution is to install non-functional “dummy” DIMMs into each unoccupied DIMM slot. This adds extra cost for each of the dummy printed circuit board (PCB) components. Using dummy DIMMs also requires that a human operator guarantee that dummy DIMMs are installed in all slots not occupied by real DIMMs. In the event that a dummy DIMM is left uninstalled, air bypass is encountered which can contribute to overheating of the installed DIMMs. Electronic methods of sensing the presence of real or dummy DIMMs can be implemented to detect any empty slots. This adds additional cost to the device. The cost increase is for the electronic components used to detect the empty slots as well as the cost for dummy DIMMs. Dummy DIMMs can get lost or thrown away in the process of updating DIMMs in a computer system over time. In the event that a working DIMM is removed from a system, a dummy DIMM to replace it with may not be available to the operator.

A second solution is to install a removable baffle above the entire array of DIMMs. The baffle does not fill any unoccupied slots. The baffle simply fills the physical volume directly above a full bank of DIMMs and forces air down into the DIMM array. As such, any non-occupied DIMMs do present a low impedance area where air can escape without properly cooling the installed and adjacent DIMMs. To compensate for this effect, upstream fans are typically located closer to the DIMMs and the velocity stream of the air pushes the air into the entire array of DIMMs, even when empty slots are encountered. In cases where the fans cannot be located in close proximity to the DIMMs, the only solution may be to use dummy DIMMs.

### BRIEF DESCRIPTION OF THE DRAWINGS

FIG. 1 is an isometric view of a memory board assembly 100.

FIG. 2 is an isometric view of an air flow redirection device 200 in an example embodiment of the invention.

### DETAILED DESCRIPTION

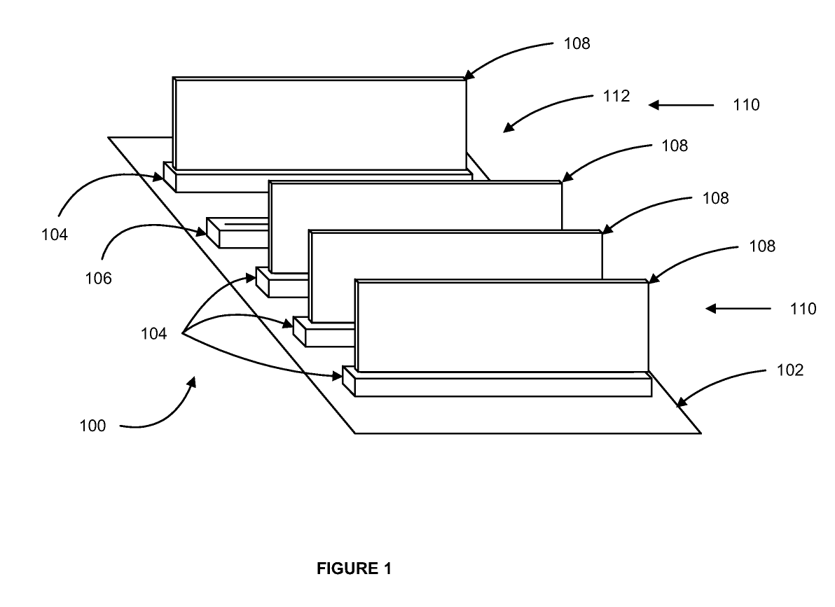

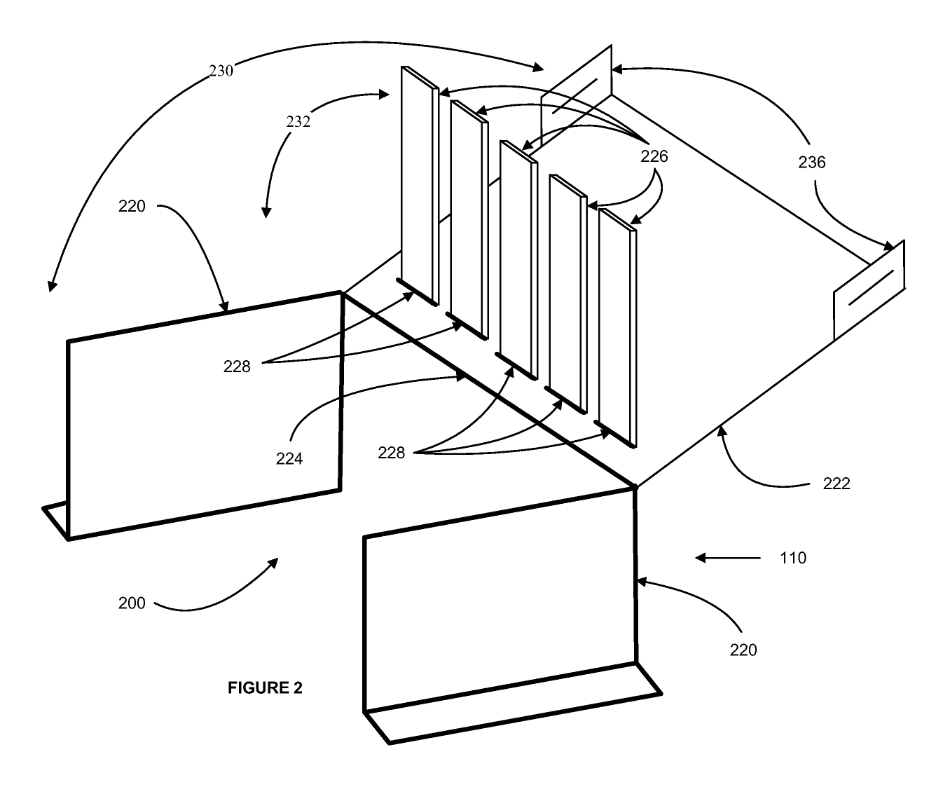

FIG. 1-2 and the following description depict specific examples to teach those skilled in the art how to make and use the best mode of the invention. For the purpose of teaching inventive principles, some conventional aspects have been simplified or omitted. Those skilled in the art will appreciate variations from these examples that fall within the scope of the invention. Those skilled in the art will appreciate that the features described below can be combined in various ways to form multiple variations of the invention. As a result, the invention is not limited to the specific examples described below, but only by the claims and their equivalents.

FIG. 1 is an isometric view of a memory board assembly 100. Memory board assembly 100 comprises primary memory board 102, a plurality of connectors 104 mounted onto primary memory board 102 and loaded with secondary memory boards 108, and an empty connector 106 mounted onto primary memory board 102. In some configurations of memory board assembly (not shown), an optional secondary memory board may be installed in empty connector 106.

During normal operation, air is forced into memory board assembly 100 as indicated by arrows 110. Empty connector 106 creates a gap or open/empty region 112 in the memory board assembly 100. The gap or open/empty region 112 creates an imbalance in airflow impedance across memory board assembly 100. Air flowing in the direction of arrows 110 may flow into gap or open/empty region 112 thereby reducing the air flow across the plurality of secondary memory boards 108.

FIG. 2 is an isometric view of air flow redirection device 200 in an example embodiment of the invention. Air flow redirection device 200 comprises a frame 220, a plate 222, locking features 236, primary hinge 224, a plurality of secondary hinges 228, and a plurality of blocking fingers 226. Plate 222 is attached to frame 220 with primary hinge 224, allowing plate to be rotated in the direction of arrow 230. Plate 222 is shown in the open position. The plurality of blocking fingers 226 are mounted onto plate 222 with the plurality of secondary hinges 228 allowing the plurality of blocking fingers to rotate in the direction indicated by arrow 232. In one example embodiment of the invention, the plurality of blocking fingers may be spaced along a single secondary hinge. The plurality of blocking fingers 226 are spring loaded such that the plurality of blocking fingers are urged in the direction away from plate 222. Locking features 236 are attached to each side of plate 222 and lock plate 222 onto frame 220 when plate 222 is rotated into the closed position on top of frame 220.

In one example embodiment of the invention, gaps may be located between the blocking fingers 226 (as shown in FIG. 2). In another example embodiment of the invention, blocking fingers 226 would be located adjacent to one-another to maximize the blockage of airflow between the blocking fingers 226. In another embodiment of the invention, blocking fingers 226 may be fabricated from two parts. The first part, part A, forms a rigid or semi-rigid blocking finger similar to the one shown in FIG. 2, only narrower in width. The width of part A is selected such that part A is too narrow to contact the DIMM components on either side as the blocking finger moves into an empty/open area. The second part, part B, is a thin flexible foam that attaches to the front face of part A and is wider than part A. As such, the foam extends beyond both sides of part A and will gently move/deform if and when it encountered side-located DIMM components as it moves into an empty/open region.

In one example embodiment of the invention, torsion springs may be incorporated into hinges 228. In another example embodiment of the invention, torsion springs may be mounted beside hinges 228. In another example embodiment of the invention, compression springs may be used to force blocking fingers in the direction away from plate 222.

In one example embodiment of the invention, air flow redirection device 200 may be mounted onto a printed circuit board (PCB), for example primary memory board 102. In another example embodiment of the invention, air flow redirection device 200 may be part of a rack that is configured to have PC assemblies installed into slots or mounting systems in the rack. In another embodiment of the invention, plate 222 may be incorporated into a top cover of a PCB sheet metal tray/enclosure. In this case the PCB mounts to a metal tray/pan, and a removable top cover is installed vertically onto the PCB+tray assembly. As the cover is installed down onto the board, the blocking fingers rotate off any installed DIMMs, or insert into the non-occupied DIMM slots. In this example embodiment of the invention, the air flow redirection device is installed into the closed position using a translation instead of a rotation.

In operation, frame 220 is aligned with PC assembly 100 with the primary hinge 224 located near the ends of, and perpendicular to, the connectors 104 on PC assembly 100. Plate 222 is rotated away from frame 220 into the open position, allowing secondary memory boards 108 to be loaded into connectors 104. Once all the secondary memory boards 108 are loaded into connectors 104, plate 222 is rotated into the closed position on top of frame 220. Locking features 236 hold plate 222 into the closed position. Spring loaded blocking fingers 226 will contact the top of the installed secondary memory boards 108, and be forced towards plate 222. Spring loaded blocking fingers 226 that are aligned with a connector that is empty will be swung down into the gap or empty/open space created by the empty connector in PC assembly 100. The blocking fingers aligned with empty connectors block air flowing in the direction of arrows 110, and force the air between the installed secondary memory boards 108.

In one embodiment of the invention, locking features 236 may be screws or other fasteners that require tools. In another example embodiment of the invention, locking features 236 may be configured to activate without the use of tools, for example flexible tabs that snap into place, spring loaded pins that snap into place, or the like.

Because spring loaded blocking fingers 226 automatically block gaps or empty/open spaces created by empty connectors, dummy DIMMs or additional ducting is not required. In one example embodiment of the invention, the installation of the PC assembly 100 can not be completed when plate 222 is left in the open position. This ensures that plate 222 is located in the closed position with blocking fingers 226 swung into any open spaces when PC assembly is completely installed.

The example above has DIMMs as the optional components in the PC assembly. This invention is not limited to DIMMs but may be used with any optional component in a PC assembly.

What is claimed is:

1. An air flow redirection device, comprising:
a frame having a main hinge coupled to a top back edge of the frame;
a plate having a first edge coupled to the main hinge, the plate configured to rotate about the main hinge from an open position to a closed position wherein in the closed position the plate rests on top of the frame with a bottom side of the plate facing a bottom of the frame;
a plurality of blocking fingers wherein each of the plurality of blocking fingers has a first end and where the first end of each of the plurality of blocking fingers is coupled to the bottom side of the plate with a secondary hinge and where the plurality of first ends form a line parallel with, and adjacent to, the primary hinge;
a plurality of springs wherein each one of the plurality of springs is coupled to one of the plurality of blocking fingers and configured to force the plurality of blocking fingers away from the plate.

2. The air flow redirection device of claim 1, further comprising:
a locking feature attached to the plate and configured to couple to the frame and hold the plate in the closed position.

3. The air flow redirection device of claim 1, wherein the plurality of springs are selected from the group consisting of: torsion springs, compression springs.

4. The air flow redirection device of claim 1, wherein the plurality of blocking fingers are generally thin rectangular slabs and where the first end is a narrow side of the generally thin rectangular slab.

5. The air flow redirection device of claim 1, wherein the plurality of blocking fingers comprise:
a first rectangular part made from a stiff material having a first width;
a second rectangular part made from a flexible material and attached to a front face of the first rectangular, the second rectangular part having a second width where the first width is smaller than the second width.

6. The air flow redirection device of claim 1, wherein the frame is mounted onto a PC assembly.

7. The air flow redirection device of claim 1, wherein the frame has a slot configured to mount a PC board assembly parallel to the plate when the plate is in the closed position.

8. The air flow redirection device of claim 1, wherein the second hinge is a single hinge with the plurality of blocking fingers mounted along a length of the secondary hinge.

9. The air flow redirection device of claim 1, wherein the plate, when in the open position, inhibits the insertion of a PC assembly into a mating component.

10. A method for redirecting airflow, comprising:
installing a plurality of components into a plurality of connectors on a PC assembly wherein at least one of the plurality of connector is left empty;
moving a plate from an open position into a closed position wherein in the closed position a plurality of spring loaded blocking fingers coupled to the plate are urged towards the plurality of connectors and where at least one of the plurality of spring loaded blocking fingers that is aligned with the at least one empty connector is positioned in a space near one end of the at least one empty connector thereby blocking airflow into the space.

11. The method for redirecting airflow of claim 9, wherein the plurality of spring loaded blocking fingers that are aligned with connectors loaded with a component, rest against a top side of the component and are forced towards the plate.

12. The method for redirecting airflow of claim 9, further comprising:
locking the plate in the closed position.

13. The method for redirecting airflow of claim 9, wherein the plate is translated using a linear motion when moving the plate from the open position into the closed position.

14. The method for redirecting airflow of claim 9, wherein the plate is moved using a rotational motion when moving the plate from the open position into the closed position.

15. An air flow redirection device, comprising:
a frame having a rectangular top;
a thin rectangular plate having a first edge, the plate configured to attach to the top of the frame with a bottom side of the plate facing a bottom of the frame;
a plurality of blocking fingers wherein each of the plurality of blocking fingers has a first end and where the first end of each of the plurality of blocking fingers is coupled to the bottom side of the plate with a hinge and where the plurality of first ends form a line parallel with, and adjacent to, the first edge;
a plurality of springs wherein each one of the plurality of springs is coupled to one of the plurality of blocking fingers and configured to force the plurality of blocking fingers away from the plate.

16. The air flow redirection device of claim 15, wherein the plurality of springs are selected from the group consisting of: torsion springs, compression springs.

17. The air flow redirection device of claim 15, further comprising:
a locking feature attached to the plate wherein the locking feature forms a snap fit against the frame thereby holding the plate to the top of the frame.

18. The air flow redirection device of claim 15, wherein the plurality of blocking fingers comprise:
a first rectangular part made from a stiff material having a first width;
a second rectangular part made from a flexible material and attached to a front face of the first rectangular, the second rectangular part having a second width where the first width is smaller than the second width.

19. An air flow redirection device, comprising:
a frame;
a plate having a first edge coupled to the frame along a top back edge of the frame with a main hinge, the plate configured to rotate about the main hinge from an open position to a closed position wherein in the closed position the plate rests on top of the frame with a bottom side of the plate facing a bottom of the frame;
a plurality of blocking fingers wherein each of the plurality of blocking fingers has a first end and where the first end of each of the plurality of blocking fingers is attached to the bottom side of the plate with a secondary hinge and where the secondary hinges form a line parallel with, and adjacent to, the primary hinge;
a means for forcing the plurality of blocking fingers away from the plate.
